(19) United States
(12) Patent Application Publication
(10) Pub. No.: US 2013/0299951 A1
(43) Pub. Date: Nov. 14, 2013

(54) FIN STRUCTURE

(71) Applicant: United Microelectronics Corp., Hsinchu (TW)

(72) Inventor: Yu-Cheng Tung, Kaohsiung City (TW)

(21) Appl. No.: 13/942,258

(22) Filed: Jul. 15, 2013

Related U.S. Application Data
(62) Division of application No. 13/368,754, filed on Feb. 8, 2012.

(51) Int. Cl. H01L 29/06

(52) U.S. Cl. CPC H01L 29/06
USPC 257/623

(57) ABSTRACT

Provided is a fin structure including a fin and two insulating layers. The fin is disposed on a substrate, wherein an upper portion is narrower than a lower portion of the fin, and the fin has an inverse T shape. The insulating layers are disposed at two sides of the fin and at least expose the upper portion of the fin.

### CROSS-REFERENCE TO RELATED APPLICATION

This application is a divisional of and claims the priority benefit of U.S. application Ser. No. 13/368,754 filed on Feb. 8, 2012, now pending. The entirety of the above-mentioned patent application is hereby incorporated by reference herein and made a part of specification.

### BACKGROUND OF THE INVENTION

1. Field of Invention

The present invention relates to a semiconductor device and a method of forming the same, and more generally to a fin structure and a method of forming the same.

2. Description of Related Art

Along with rapid progress in semiconductor technology, dimensions of integrated circuits (IC) are reduced and the degree of integration thereof is increased continuously to further enhance the speed and performance of the device. Generally speaking, with the design trend of scaling down the device size, the channel length of a transistor is accordingly shortened to facilitate the operation speed of the device. However, such design would cause the transistor to have problems such as serious leakage current, short channel effect, ‘on’ current decrease, etc.

In recent years, a multi-gate structure is proposed to overcome the above-mentioned problems. A gate in the multi-gate structure surrounds the channel region, so that the entire channel region is subjected to the influence of the gate electric field. Ultimately, the ‘on’ current of the device is increased and the leakage current is reduced. A fin-type field effect transistor (FinFET) is a transistor having a multi-gate structure. However, the fin transistor has a three-dimensional structure, which is more complicated than the conventional structure and is more difficult in manufacturing. Moreover, the fin transistor is usually formed on a silicon-on-insulator (SOI) substrate, so that the manufacturing process thereof is difficult to compatible with the existing silicon substrate process. In addition, due to the special process of the fin transistor, certain problems occur when the fin transistor is integrated with the existing planar transistor. On the other hand, the fin structures for forming the fin transistor have a very small gap therebetween. Therefore, the epitaxial layers respectively around the neighboring fin structures are easy to connect to each other.

### SUMMARY OF THE INVENTION

The present invention further provides a fin structure to prevent the epitaxial layers respectively around the neighboring fin structures from connecting to each other.

The present invention further provides a fin structure including a fin and two insulating layers. The fin is disposed on a substrate, wherein an upper portion is narrower than a lower portion of the fin, and the fin has an inverse T shape. The insulating layers are disposed at two sides of the fin and at least expose the upper portion of the fin.

According to an embodiment of the present invention, the insulating layers cover a whole sidewall of the lower portion of the fin.

According to an embodiment of the present invention, the insulating layers expose a portion of a sidewall of the lower portion of the fin.

According to an embodiment of the present invention, a recess is disposed between the fin and each insulating layer.

According to an embodiment of the present invention, the fin structure further includes an epitaxial layer covering a surface of the fin exposed by the insulating layers and filling the recesses.

According to an embodiment of the present invention, the fin structure further includes an epitaxial layer covering a surface of the fin exposed by the insulating layers.

The fin structure of the present invention has a narrower upper portion and a wider lower portion, so as to prevent the epitaxial layers respectively around the neighboring fin structures from connecting to each other.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A to 1F schematically illustrate cross-sectional views of a method of forming a fin structure according to a first embodiment of the present invention.

FIGS. 2A to 2D schematically illustrate cross-sectional views of a method of forming a fin structure according to a second embodiment of the present invention.

FIGS. 3A to 3E schematically illustrate cross-sectional views of a method of forming a fin structure according to a third embodiment of the present invention.

FIGS. 4A to 4D schematically illustrate cross-sectional views of a method of forming a fin structure according to a fourth embodiment of the present invention.

FIGS. 5A to 5B schematically illustrate cross-sectional views of a method of forming a fin structure according to a fifth embodiment of the present invention.

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

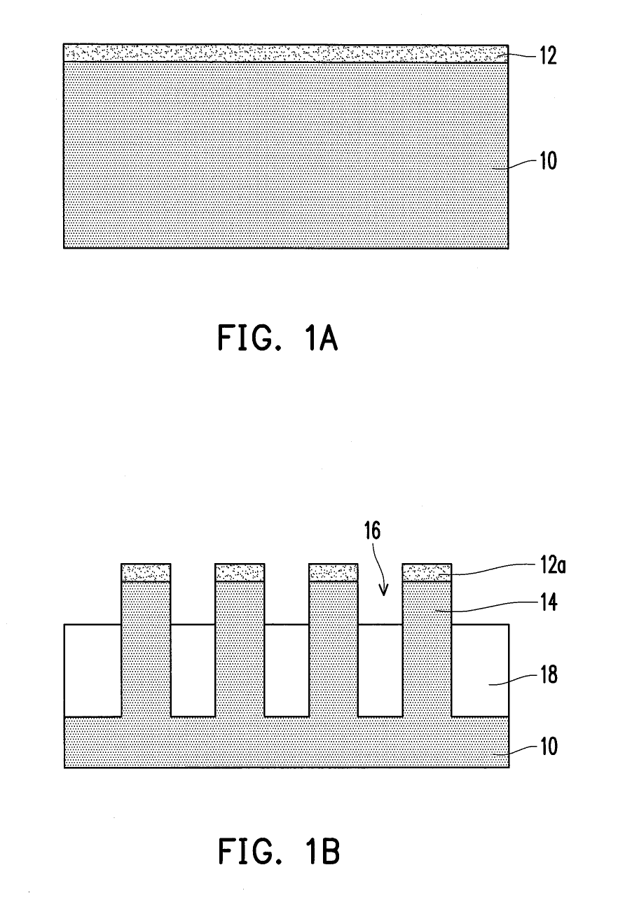

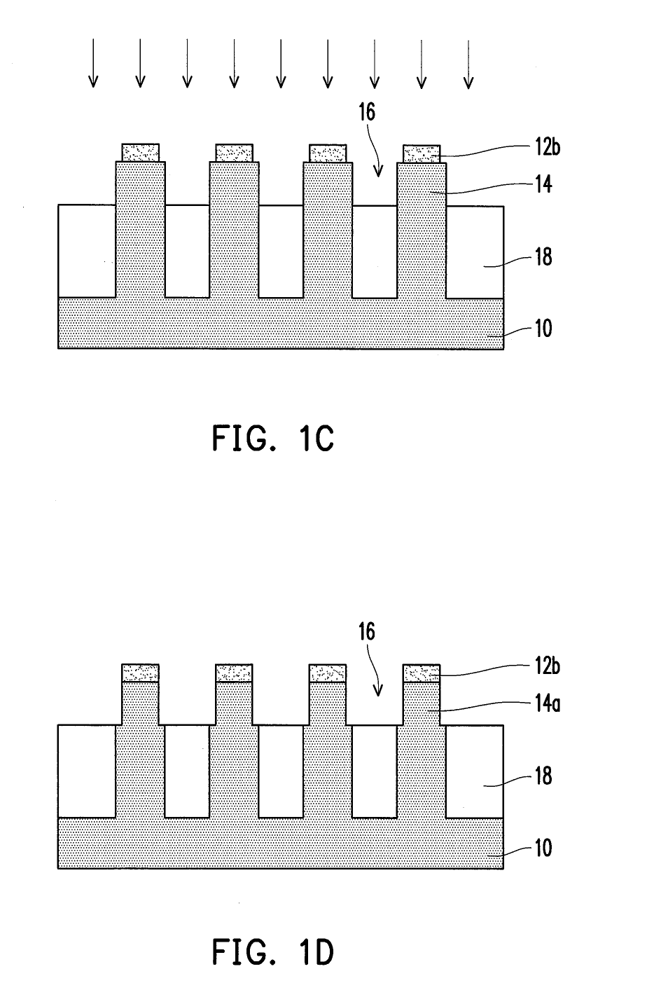

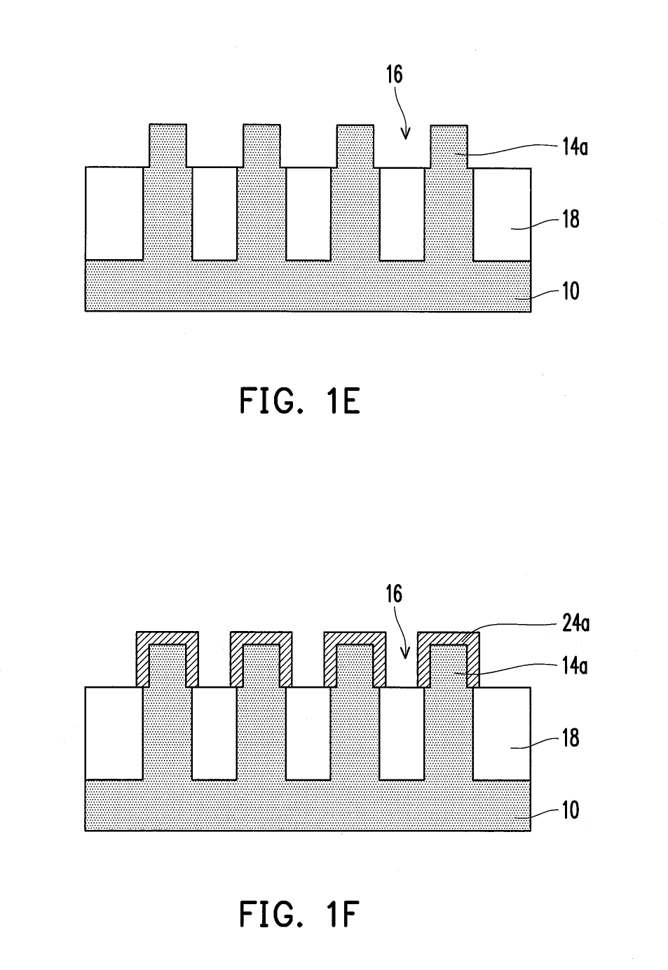

FIGS. 1A to 1F schematically illustrate cross-sectional views of a method of forming a fin structure according to a first embodiment of the present invention.

Referring to FIG. 1A, a hard mask material layer 12 is formed on a substrate 10. The substrate 10 includes a semiconductor material, such as silicon. The hard mask material layer 12 can be a single material layer or constituted by more than two material layers. In an embodiment, the hard mask material layer 12 is constituted by, from bottom to top, a silicon oxide layer and a silicon nitride layer, for example. The method of forming the silicon oxide layer and the silicon nitride layer includes performing a chemical vapour deposition (CVD) process.

Referring to FIG. 1B, the hard mask material layer 12 is patterned by photolithography and etching processes, so as to form a hard mask layer 12a. Thereafter, a portion of the substrate 10 is etched away, so as to form trenches 16. The remaining substrate 10 forms a fin 14 between the neighboring trenches 16. In fact, the trenches 16 surrounds the fin 14 from topview. Below description will illustrate from cross-sectional view. Afterwards, an insulating layer 18 is formed in each trench 16 exposing an upper portion of each fin 14. The method of forming the insulating layer 18 in each trench 16 includes the following steps. An insulating material layer is formed on the substrate 10. Then, a planarization process is performed by using the hard mask layer 12a as a stop layer, so as to remove the insulating material layer above the hard mask layer 12a. Afterwards, a portion of the insulating material layer in each trench 16 is removed, and the insulating material layer left on the bottom of each trench 16 is an insulating layer 18. The insulating material layer includes silicon oxide, and the forming method thereof includes performing a CVD process. The planarization process is a chemical mechanical polishing (CMP) process, for example.

Referring to FIGS. 1C and 1D, the step of trimming the upper portion of each fin 14 is preformed, so that the trimmed upper portion is narrower than the lower portion of each fin 14a. Accordingly, each fin 14a is formed in the shape of an inverse T having a narrower upper portion and a wider lower portion. Each fin 14a is the fin structure of the present invention, as shown in FIG. 1D.

Specifically, referring to FIG. 1C, in this embodiment, the step of trimming the upper portion of each fin 14 includes tuning the hard mask layer 12a to form a hard mask layer 12b. The hard mask layer 12b has a smaller dimension than that of the hard mask layer 12a, and exposes a portion of the surface of each fin 14.

Referring to FIG. 1D, a portion of each fin 14 not covered by the hard mask layer 12b and the insulating layers 18 is etched by using the hard mask layer 12b as a mask. The etching method is, for example, an anisotropic etching process, and the etching depth can be controlled by a time mode. In this embodiment, with a time mode control, each fin 14a is a fin structure in the shape of an inverse T having a narrower upper portion and a wider lower portion. Two insulating layers 18 cover the whole sidewall of the lower portion of each fin 14a while exposing the sidewall and top of the upper portion of each fin 14a and exposing the top of the lower portion of each fin 14a.

Referring to FIG. 1E, the hard mask layer 12b is removed. The method of removing the hard mask layer 12b includes performing an etching process, such as an anisotropic etching process.

Referring to FIG. 1F, an epitaxial layer 24a is formed on the exposed surface of each fin 14a. The epitaxial layers 24a are for increasing the carrier mobility in the channels, and each of them can be a single-material layer, a two-material layer or a multi-material layer. Each epitaxial layer 24a includes a III-V semiconductor compound, a IV group element or a combination thereof. The IV group element is silicon, germanium, SiGe, SiC or graphene, for example. The III-V semiconductor compound is GaAs, for example. In a PMOS device, each epitaxial layer 24a can be a SiGe single layer, or constituted by a SiGe layer and a silicon layer. In an NMOS device, each epitaxial layer 24a can be a SiC single layer, or constituted by a SiC layer and a silicon layer. The method of forming the epitaxial layers 24a includes performing an selective epitaxial growth (SEG) process.

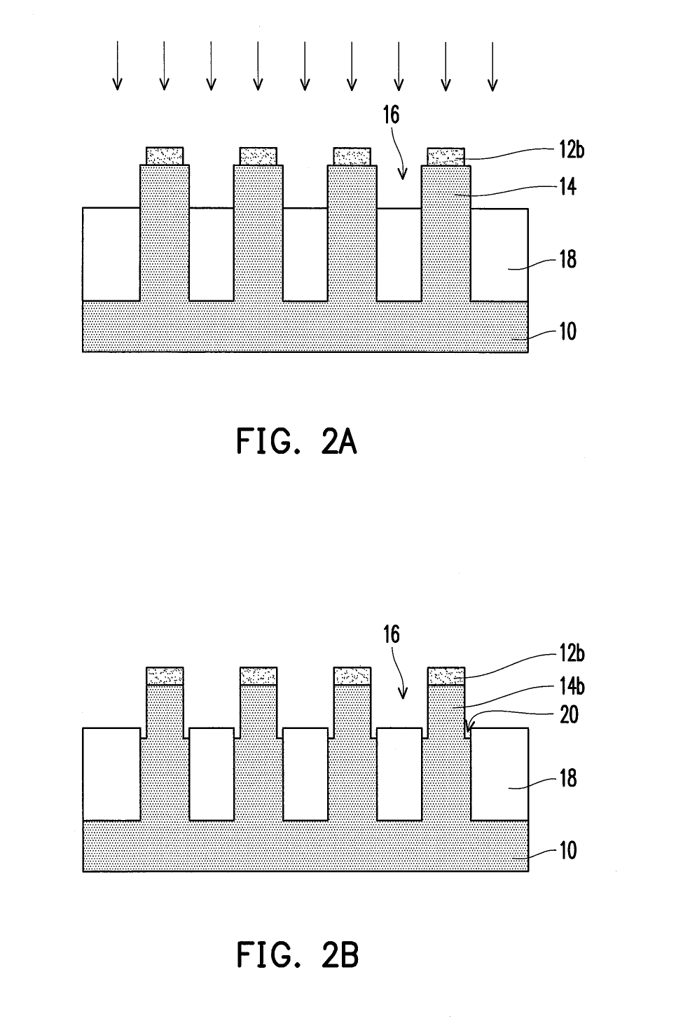

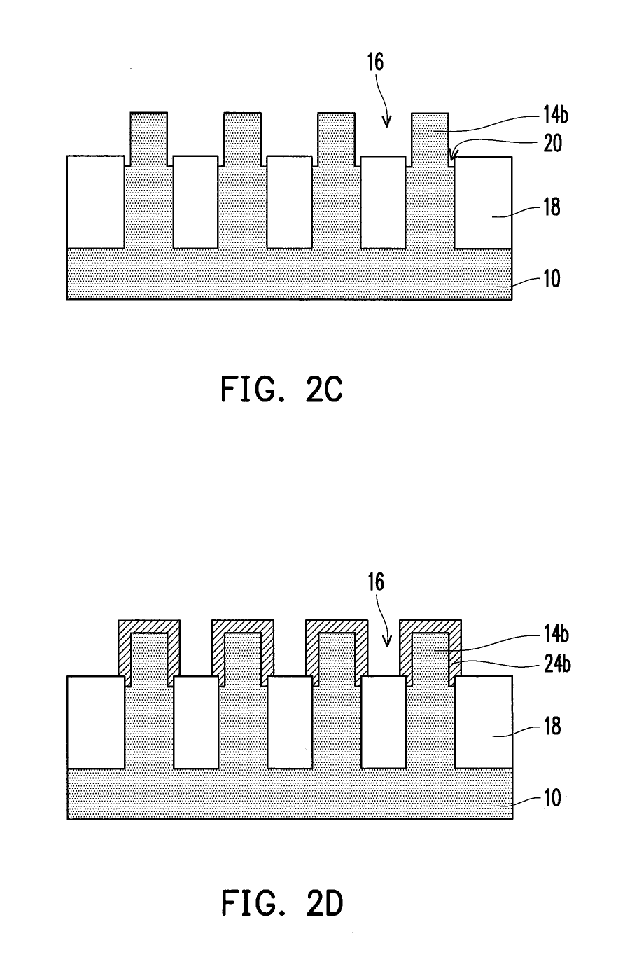

FIGS. 2A to 2D schematically illustrate cross-sectional views of a method of forming a fin structure according to a second embodiment of the present invention.

According to the described method, the hard mask material layer 12 is patterned and a portion of the substrate 10 is removed, so as to form the hard mask layer 12a, trenches 16 and fins 14. Thereafter, an insulating layer 18 is formed in each trench 16 exposing the upper portion of each fin 14, as shown in FIG. 1A.

Referring to FIGS. 2A and 2B, the step of trimming the upper portion of each fin 14 is preformed, so that the trimmed upper portion is narrower than the lower portion of each fin 14b. Accordingly, each fin 14b is formed in the shape of an inverse T having a narrower upper portion and a wider lower portion. Each fin 14b is the fin structure of the present invention, as shown in FIG. 2B.

Specifically, referring to FIG. 2A, in this embodiment, the step of trimming the upper portion of each fin 14 includes tuning the hard mask layer 12a to form a hard mask layer 12b. The hard mask layer 12b has a smaller dimension than that of the hard mask layer 12a, and exposes a portion of the surface of each fin 14.

Referring to FIG. 2B, a portion of each fin 14 exposed by the hard mask layer 12a and the neighboring insulating layers 18 is etched away by using the hard mask layer 12b as a mask, and the same etching step further etches downward to remove a portion of each fin 14 adjacent to the neighboring insulating layer 18, and thus, a recess 20 is formed between each remaining fin 14b and the neighboring insulating layer 18. The etching method is, for example, an anisotropic etching process, and the etching depth can be controlled by a time mode.

Referring to FIG. 2C, the hard mask layer 12b is removed. The method of removing the hard mask layer 12b includes performing an etching process, such as an anisotropic etching process. Each remaining fin 14b is a fin structure in the shape of an inverse T having a narrower upper portion and a wider lower portion. It is noted that each fin 14b has an upper portion longer than that of each fin 14a (or fin structure) in FIG. 1E. Two insulating layers 18 cover the whole sidewall of the lower portion of each fin 14b while exposing the sidewall and top of the upper portion of each fin 14b and exposing the top of the lower portion of each fin 14b. Further, a recess 20 is disposed between each fin 14b and the neighboring insulating layer 18, so as to expose a portion of the sidewall of the insulating layer 18.

Referring to FIG. 2D, an epitaxial layer 24b is formed on the exposed surface of each fin 14b. The material and forming method of the epitaxial layers 24b are similar to those of the epitaxial layers 24a in the first embodiment, and the details are not iterated herein.

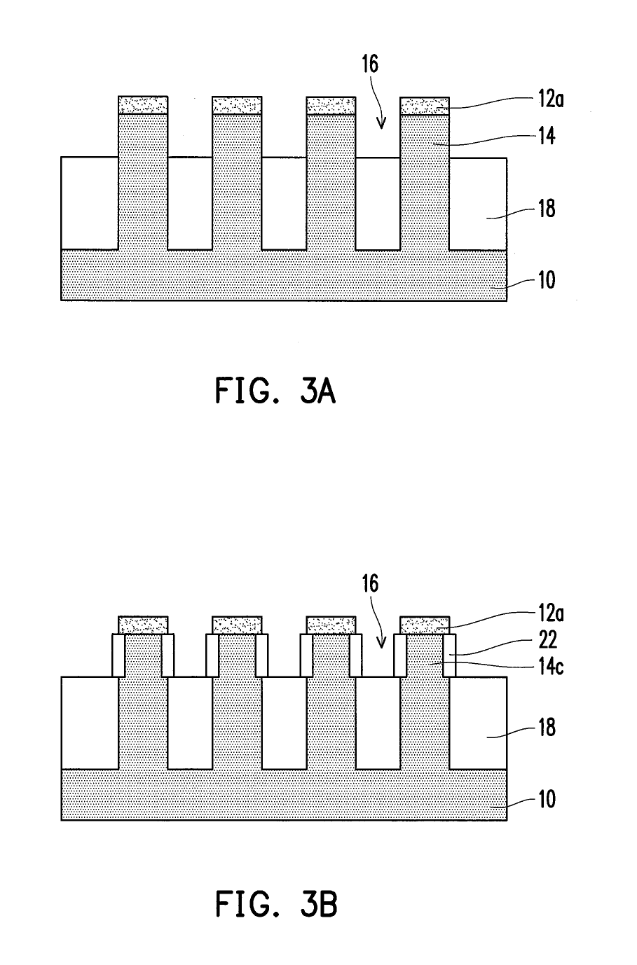

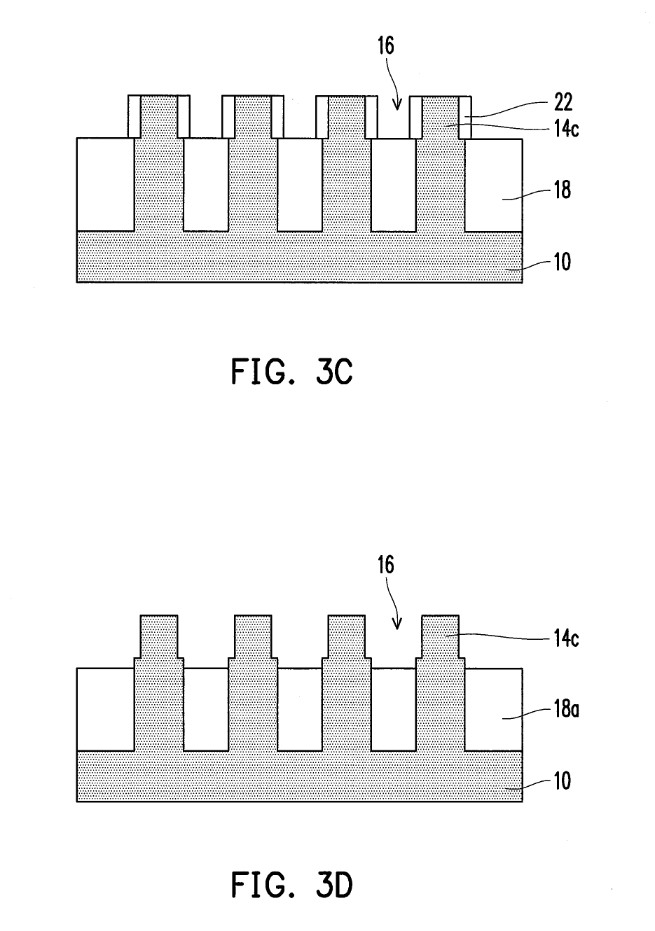

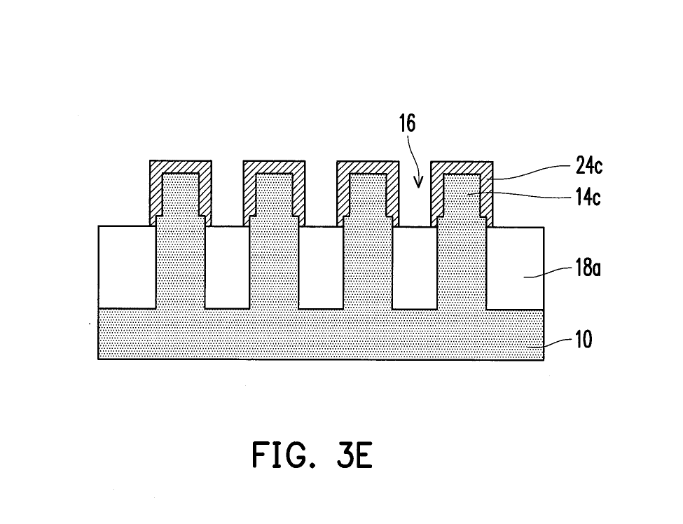

FIGS. 3A to 3E schematically illustrate cross-sectional views of a method of forming a fin structure according to a third embodiment of the present invention.

Referring to FIG. 3A, according to the described methods in the first embodiment, the hard mask material layer 12 is patterned and a portion of the substrate 10 is removed, so as to form the hard mask layer 12a, trenches 16 and fins 14. Thereafter, an insulating layer 18 is formed in each trench 16 exposing the upper portion of each fin 14.

Referring to FIGS. 3B and 3D, the step of trimming the upper portion of each fin 14 is preformed, so that the trimmed upper portion is narrower than the lower portion of each fin 14c. Accordingly, each fin 14c is formed in the shape of an inverse T having a narrower upper portion and a wider lower portion. Each fin 14c is the fin structure of the present invention, as shown in FIG. 3D.

Specifically, referring to FIG. 3B, in this embodiment, the step of trimming the upper portion of each fin 14 includes performing an oxidation process that at least oxidizes the sidewall of the upper portion of each fin 14 exposed by the hard mask layer 12a and the neighboring two insulating layers 18 to form an oxide 22. In an embodiment, each fin 14 includes silicon, and the oxidation process includes a thermal oxidation process.

Referring to FIG. 3C, the hard mask layer 12a is removed, so as to expose the non-oxidized top of each fin 14c. The method of removing the hard mask layer 12a includes performing an etching process, such as an anisotropic etching process.

Referring to FIG. 3D, the oxides 22 are moved, so as to expose a sidewall of the upper portion of each fin 14c. The method of removing the oxides 22 includes performing an etching process, such as an anisotropic etching process. In an embodiment, each insulating layer 18 is a silicon oxide layer, and a portion of the insulating layers 18 are removed during the step of removing the oxides 22. Two remaining insulating layers 18a only cover a portion of the sidewall of the lower portion of each fin 14c, so as to expose the top and another portion of the lower portion of each fin 14c. Each remaining fin 14c is a fin structure in the shape of an inverse T having a narrower upper portion and a wider lower portion.

Referring to FIG. 3E, an epitaxial layer 24c is formed on the exposed surface of each fin 14c. The material and forming method of the epitaxial layers 24c are similar to those of the epitaxial layers 24a in the first embodiment, and the details are not iterated herein.

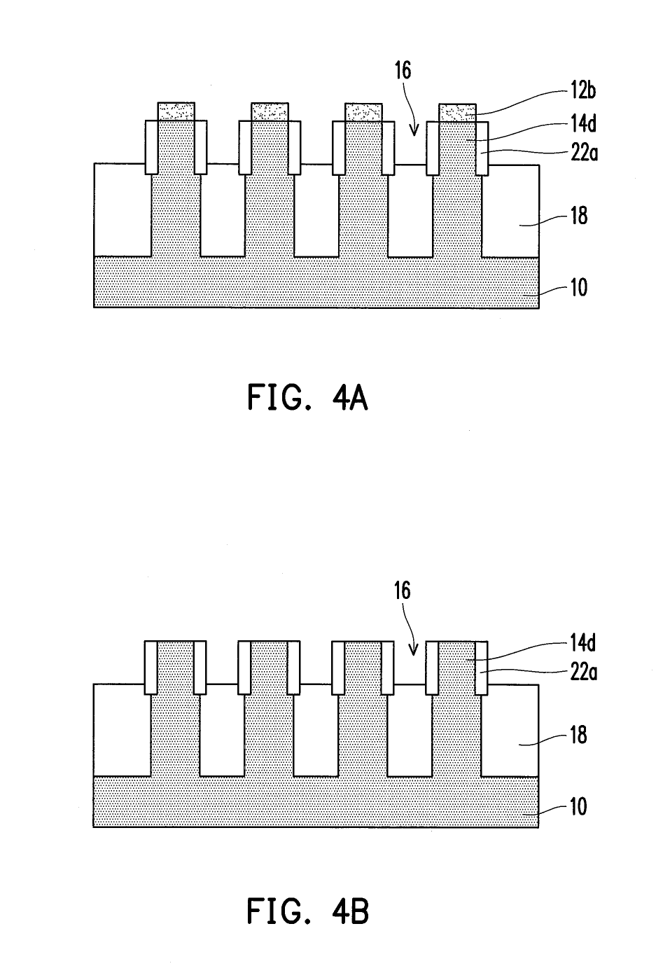

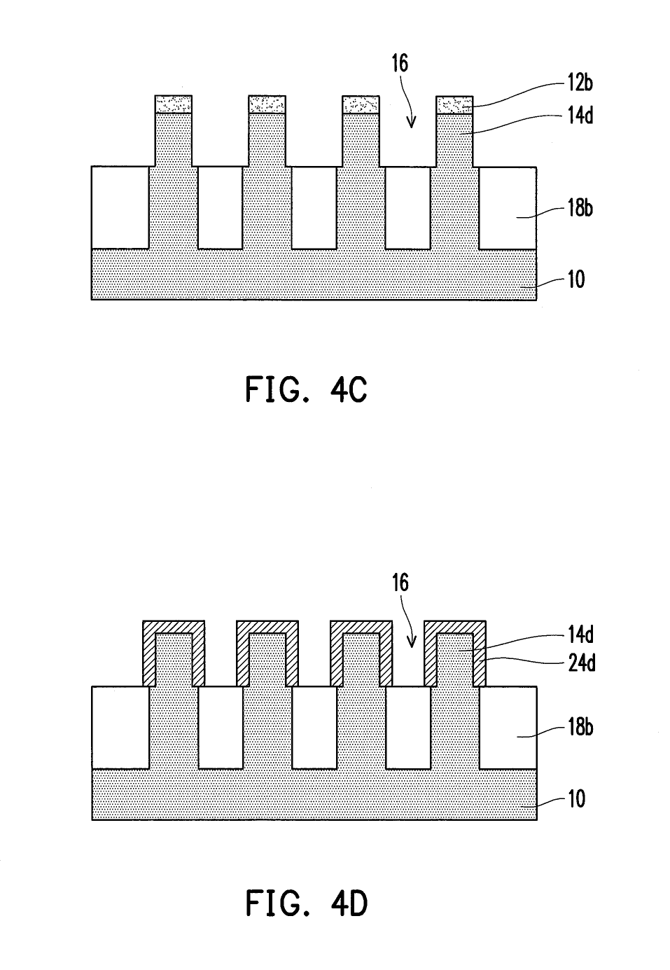

FIGS. 4A to 4C schematically illustrate cross-sectional views of a method of forming a fin structure according to a fourth embodiment of the present invention.

In another embodiment, according to the described methods in the first embodiment, the hard mask material layer 12 is patterned and a portion of the substrate 10 is removed, so as to form the hard mask layer 12a, trenches 16 and fins 14. Thereafter, an insulating layer 18 is formed in each trench 16 exposing the upper portion of each fin 14.

Referring to FIGS. 4A and 4C, the step of trimming the upper portion of each fin 14 is preformed, so that the trimmed upper portion is narrower than the lower portion of each fin 14d. Accordingly, each fin 14d is formed in the shape of an inverse T having a narrower upper portion and a wider lower portion. Each fin 14d is the fin structure of the present invention, as shown in FIG. 4C.

Specifically, referring to FIG. 4A, in this embodiment, the step of trimming the upper portion of each fin 14 includes performing an oxidation process. However, in this embodiment, the oxidation process not only oxidizes the sidewall of the upper portion of each fin 14 exposed by the hard mask layer 12a and the neighboring two insulating layers 18, but also oxidizes a portion of each fin 14 adjacent to the neighboring insulating layer 18, and thus, an oxide 22a is formed between each fin 14d and the neighboring insulating layer 18.

Referring to FIG. 4B, the hard mask layer 12a is removed, so as to expose the non-oxidized top of each fin 14d. The method of removing the hard mask layer 12a includes performing an etching process, such as an anisotropic etching process.

Referring to FIG. 4C, the oxides 22a are removed, so as to expose a sidewall of the upper portion of each fin 14d. The method of removing the oxides 22a includes performing an etching process, such as an anisotropic etching process. In an embodiment, each insulating layer 18 is a silicon oxide layer, and a portion of the insulating layers 18 are removed during the step of removing the oxides 22a. Therefore, by appropriately controlling the depth of the formed oxides 22 and the process time of the removing step, two remaining insulating layers 18b completely cover the sidewall of the lower portion of each fin 14d, so as to expose the top of the lower portion of each fin 14d. Each remaining fin 14d is a fin structure in the shape of an inverse T having a narrower upper portion and a wider lower portion. It is noted that each fin 14d has an upper portion longer than that of each fin 14c (or fin structure) in FIG. 3D.

Referring to FIG. 4D, an epitaxial layer 24d is formed on the exposed surface of each fin 14d. The material and forming method of the epitaxial layers 24d are similar to those of the epitaxial layers 24a in the first embodiment, and the details are not iterated herein.

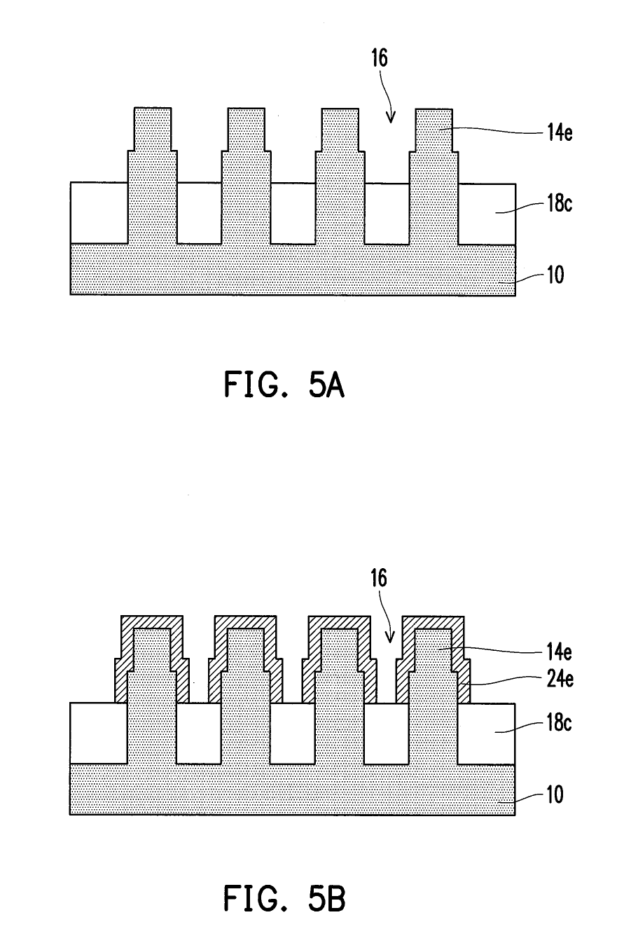

FIGS. 5A to 5B schematically illustrate cross-sectional views of a method of forming a fin structure according to a fourth embodiment of the present invention.

Referring to FIG. 5A, after the fin 14d of the fourth embodiment as shown in

FIG. 4C is formed, a portion of each insulating layer 18b is further removed to reduce the thickness of each insulating layer 18b. Therefore, two remaining insulating layers 18c only cover a portion of the sidewall of the lower portion of each fin 14e, so as to expose another portion of the sidewall of the lower portion of each fin 14e. The method of removing the portion of each insulating layer 18 includes performing an etching back process, and the removing thickness can be controlled by a time mode.

Each fin 14e in this embodiment is a fin structure in the shape of an inverse T having a narrower upper portion and a wider lower portion. It is noted that each fin 14e has an upper portion longer than that of each fin 14c (or fin structure) in FIG. 3D.

Referring to FIG. 5B, an epitaxial layer 24e is formed on the exposed surface of each fin 14e. The material and forming method of the epitaxial layers 24e are similar to those of the epitaxial layers 24a in the first embodiment, and the details are not iterated herein.

In the third to fifth embodiments, the hard mask layer 12a is removed before the oxides 22 or 22a are removed. However, the present invention is not limited thereto. In another embodiment, the hard mask layer 12a can be removed after the oxides 22 or 22a are removed.

The fin structure of the present invention has a narrower upper portion and a wider lower portion, so as to prevent the epitaxial layers respectively around the upper portions of the neighboring fin structures from connecting to each other. Therefore, the fin structure of the present invention is suitable for manufacturing a multi-gate field transistor.

The method of forming the fin structure of the present invention can be integrated with the existing semiconductor process.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A fin structure, comprising:
a fin, disposed on a substrate, wherein an upper portion is narrower than a lower portion of the fin, and the fin has an inverse T shape; and
two insulating layers, disposed at two sides of the fin and at least exposing the upper portion of the fin.

2. The fin structure of claim 1, wherein the insulating layers cover a whole sidewall of the lower portion of the fin.

3. The fin structure of claim 1, wherein the insulating layers expose a portion of a sidewall of the lower portion of the fin.

4. The fin structure of claim 1, wherein a recess is disposed between the fin and each insulating layer.

5. The fin structure of claim 1, further comprising an epitaxial layer covering a surface of the fin exposed by the insulating layers and filling the recesses.

6. The fin structure of claim 1, further comprising an epitaxial layer covering a surface of the fin exposed by the insulating layers.
